(19) United States
(12) Patent Application Publication
(10) Pub. No.: US 2025/0391746 A1
(43) Pub. Date: Dec. 25, 2025

(54) PACKAGE STRUCTURE AND PACKAGE METHOD

(71) Applicant: JCET GROUP CO., LTD., Jiangsu Province (CN)

(72) Inventors: Yuesheng Zhang, Jiangsu Province (CN); Zhengyang Sun, Jiangsu Province (CN); Kaiyuan Yu, Jiangsu Province (CN)

(73) Assignee: JCET GROUP CO., LTD., Jiangsu Province (CN)

(21) Appl. No.: 19/246,628

(22) Filed: Jun. 23, 2025

(30) Foreign Application Priority Data
Jun. 24, 2024 (CN) 202410823810.0

(51) Int. Cl. H01L 23/495; H01L 21/48; H01L 21/56; H01L 23/00; H01L 23/31

(52) U.S. Cl. CPC H01L 23/49548; H01L 21/4871; H01L 21/561; H01L 21/565; H01L 23/3135; H01L 23/49517; H01L 23/49568; H01L 24/48; H01L 24/32; H01L 24/73; H01L 2224/32245; H01L 2224/48245; H01L 2224/73265; H01L 2924/1715

(57) ABSTRACT

A semiconductor package technology in which a section of a base island is trapezoidal. A die is located on an upper bottom surface of the trapezoidal base island. A lead is spaced from the base island, and a section of the lead is inverted-trapezoidal A wire electrically connects the lead to the die. According to embodiments of the disclosure, the die is in contact with a smaller-sized upper bottom surface of the base island. The smaller-sized upper bottom surface receives heat generated by the die, and a larger-sized lower bottom surface of the base island dissipates the heat. Heat generated by the die is rapidly dissipated to cool the die so that the die operates normally to improve the heat dissipation effect of the package structure. The inverted-trapezoidal lead has a larger-sized lower bottom surface to facilitate formation of the wire between the lead and the die.

### CROSS-REFERENCE TO RELATED APPLICATION

This application claims the benefit of priority under 35 U.S.C. § 119 from Chinese Patent Application No. 202410823810.0, filed on Jun. 24, 2024, the entire disclosure of which is hereby incorporated herein by reference.

### TECHNICAL FIELD

Embodiments of the present disclosure relate to the field of semiconductor package, and in particular to a package structure and a package method.

### BACKGROUND

The semiconductor package technology includes a variety of package forms. With the trend towards a small-sized and thinned die package structure, a quad flat no-lead package (QFN) that belongs to a flat package series is developed. The quad flat no-lead package has no leads extending outwards, and thus can be greatly reduced in size and has a short signal transmission path and a high signal transmission speed. Thus, being applicable to high-speed and high-frequency products with medium and low lead counts, the quad flat no-lead package has become a prevalent package form.

A bottom surface of the quad flat no-lead package includes a base island and leads. The base island is located at a central position of the bottom surface and exposed at the bottom surface for heat conduction. The leads surround the base island for electrical connection. In addition, a die of the quad flat no-lead package adheres to the base island.

Components that are packaged in a form of the quad flat no-lead package can be collectively referred to as QFN devices. Heat generated during operation of the packaged device in the form of the quad flat no-lead increases a temperature of the packaged device. However, when the temperature exceeds a particular limit, normal operation performance of the die will be affected. Thus, heat dissipation performance of the packaged device in the form of the quad flat no-lead needs to be improved.

### SUMMARY

A problem to be solved by embodiments of the present disclosure is to provide a package structure and a package method, so as to improve a heat dissipation capability of the package structure.

To solve the above problem, a package structure is provided in the embodiments of the present disclosure. The package structure includes: a base island, where a section of the base island is trapezoidal; a die, where the die is located on an upper bottom surface of the trapezoidal base island; a lead, where the lead is spaced from the base island, and a section of the lead is inverted-trapezoidal; and a wire, where the wire electrically connects the lead to the die.

Optionally, a side surface of the trapezoidal base island is parallel to a side surface of the inverted-trapezoidal lead.

Optionally, with a direction perpendicular to the upper bottom surface of the trapezoidal base island as a first direction, an overlapping region is provided between the base island and the lead in the first direction.

Optionally, an included angle between the upper bottom surface and a side surface of the trapezoidal base island is greater than or equal to 135° and less than or equal to 150°.

Optionally, the package structure further includes: a connection pillar, where the connection pillar is located on a lower bottom surface of the inverted-trapezoidal lead.

Optionally, the connection pillar is a cylindrical connection pillar or a C-shaped connection pillar having an opening facing away from the die.

Optionally, the package structure further includes: a plastic package layer, where the plastic package layer covers the die and the wire and fills a portion between the lead and the base island.

A package method is further provided in the embodiments of the present disclosure. The method includes: providing a frame; obliquely segmenting the frame to form a plurality of spaced base islands and a plurality of spaced electrically-conductive structures, so as to enable sections of the base islands to be trapezoidal and sections of the electrically-conductive structures to be inverted-trapezoidal; arranging dies on upper bottom surfaces of the trapezoidal base islands; connecting end portions of lower bottom surfaces of the electrically-conductive structures to the dies through wires; and segmenting electrically-conductive structures between adjacent dies, so as to form spaced leads.

Optionally, in the obliquely segmenting the frame, side surfaces of the trapezoidal base islands are parallel to side surfaces of the inverted-trapezoidal electrically-conductive structures.

Optionally, in the obliquely segmenting the frame, with a direction perpendicular to the upper bottom surface of the trapezoidal base island as a first direction, an overlapping region is provided between the base island and the electrically-conductive structure in the first direction.

Optionally, the obliquely segmenting the frame includes: etching the frame through a plasma etching technology or cutting the frame through a laser cutting technology.

Optionally, in the obliquely segmenting the frame, an included angle between the upper bottom surface and a side surface of the trapezoidal base island is greater than or equal to 135° and less than or equal to 150°.

Optionally, in the providing a frame, the frame includes a first surface and a second surface facing away from the first surface, the frame includes a plurality of component areas, and first surfaces of the component areas include first regions and second regions located around the first regions; and the obliquely segmenting the frame includes: performing oblique segmentation on the first surface to the second surface along a junction between the first region and the second region in an oblique direction facing away from the first region, so as to form the trapezoidal base island and the inverted-trapezoidal electrically-conductive structure, and the electrically-conductive structure spans a boundary between adjacent component areas.

Optionally, the package method further includes: forming a plastic package layer covering the dies, the base islands, and the electrically-conductive structures before the electrically-conductive structures between the adjacent dies are segmented; and in the segmenting electrically-conductive structures, the plastic package layer is further segmented.

Optionally, in the providing a frame, the frame includes a plurality of component areas, and the component areas include first regions and second regions located around the first regions; in the obliquely segmenting the frame, the electrically-conductive structures span boundaries between adjacent component areas; the package method further includes: forming a plurality of spaced cylindrical connection pillars on the electrically-conductive structures after the dies are formed on the base islands and before the electrically-conductive structures between the adjacent dies are segmented, where the cylindrical connection pillars are located in different component areas; and in the segmenting electrically-conductive structures between adjacent dies, segmentation is performed along the boundaries between the adjacent component areas, so as to enable different cylindrical connection pillars to be located on different leads respectively.

Optionally, in the providing a frame, the frame includes a plurality of component areas, and the component areas include first regions and second regions located around the first regions; in the obliquely segmenting the frame, the electrically-conductive structures span boundaries between adjacent component areas; the package method further includes: forming hollow rectangular structures on the electrically-conductive structures after the dies are formed on the base islands and before the electrically-conductive structures between the adjacent dies are segmented, where the electrically-conductive structures span the boundaries between the adjacent component areas; and in the segmenting electrically-conductive structures between adjacent dies, the hollow rectangular structures are segmented along the boundaries between the adjacent component areas, so as to form C-shaped connection pillars having openings facing away from the dies on different leads.

Compared with the prior art, the technical solutions in the embodiments of the present disclosure have the advantages as follows:
in the package structure according to the embodiments of the present disclosure, the section of the base island is trapezoidal; the die is located on the upper bottom surface of the trapezoidal base island; the lead is spaced from the base island, and the section of the lead is inverted-trapezoidal; and the wire electrically connects the lead to the die. In the package structure according to the embodiments of the present disclosure, the die is in contact with a smaller-sized upper bottom surface of the base island. The smaller-sized upper bottom surface receives heat generated by the die, and a larger-sized lower bottom surface of the base island dissipates the heat. Thus, the heat generated by the die is rapidly dissipated to cool the die, the die operates normally, and a heat dissipation effect of the package structure is improved. In addition, the inverted-trapezoidal lead has a larger-sized lower bottom surface to facilitate formation of the wire between the lead and the die, so that technology reliability is improved.

### BRIEF DESCRIPTION OF THE DRAWINGS

FIG. 1 to FIG. 6 are schematic structural diagrams corresponding to all steps in a first embodiment of a package method according to the present disclosure;

FIG. 7 to FIG. 9 are schematic structural diagrams corresponding to all steps in a second embodiment of a package method according to the present disclosure; and

FIG. 10 to FIG. 12 are schematic structural diagrams corresponding to all steps in a third embodiment of a package method according to the present disclosure.

### DETAILED DESCRIPTION

It can be seen from the background art that at present, heat generated during operation of a packaged device in a form of quad flat no-lead increases a temperature of the packaged device. However, when the temperature exceeds a particular limit, normal operation performance of a die will be affected. Thus, heat dissipation performance of the packaged device in the form of the quad flat no-lead needs to be improved.

To solve the technical problem, in a package structure according to embodiments of the present disclosure, a section of a base island is trapezoidal; a die is located on an upper bottom surface of the trapezoidal base island; a lead is spaced from the base island, and a section of the lead is inverted-trapezoidal; and a wire electrically connects the lead to the die. In the package structure according to the embodiments of the present disclosure, the die is in contact with a smaller-sized upper bottom surface of the base island. The smaller-sized upper bottom surface receives heat generated by the die, and a larger-sized lower bottom surface of the base island dissipates the heat. Thus, the heat generated by the die is rapidly dissipated to cool the die, the die operates normally, and a heat dissipation effect of the package structure is improved. In addition, the inverted-trapezoidal lead has a larger-sized lower bottom surface to facilitate formation of the wire between the lead and the die, so that technology reliability is improved.

To make the above objectives, features, and advantages in the embodiments of the present disclosure more apparent and easier to understand, specific embodiments of the present disclosure are described in detail below with reference to the accompanying drawings.

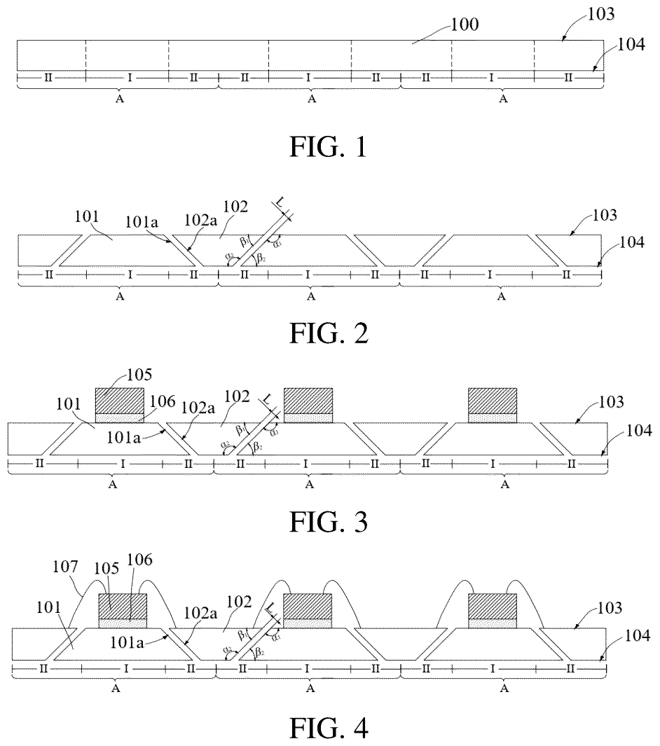

Correspondingly, the present disclosure further provides a package method. FIG. 1 to FIG. 6 are schematic structural diagrams corresponding to all steps in a first embodiment of a package method according to the present disclosure.

With reference to FIG. 1, a frame 100 is provided. The frame 100 is used as a carrier for a die package.

In the embodiment, the package method is performed in a form of quad flat no-lead. In a subsequent package process, the frame 100 is segmented into a base island and an electrically-conductive structure located around the base island.

In the subsequent package process, the frame 100 needs to be segmented to form the trapezoidal base island and the inverted-trapezoidal electrically-conductive structure. Thus, owing to good electrical conduction performance and heat conduction performance of the frame 100, the base island formed subsequently has good heat dissipation performance, and the electrically-conductive structure formed subsequently has good electrical conduction performance.

In the embodiment, a material of the frame 100 includes, but is not limited to, one or more of gold, copper, nickel, and tin.

It should be noted that when the frame 100 is obliquely segmented subsequently, to ensure that a slope on a side surface of the base island and a slope on a side surface of the electrically-conductive structure are flat and good in shape, in the step that a frame 100 is provided, a thickness of the frame 100 is greater than that of a common frame.

In the embodiment, the thickness of the frame 100 is 0.3 mm to 0.7 mm. If the thickness of the frame 100 is greater, time for obliquely segmenting the frame 100 will be long, which is not conducive to reduction in a period of the package method. In addition, unnecessary material waste will be caused. If the thickness of the frame 100 is smaller, the side surface of the base island and the side surface of the electrically-conductive structure that are formed subsequently are likely to be non-flat, and thus difficulties in machining the base island and the electrically-conductive structure are increased. In addition, since the base island formed subsequently is trapezoidal, and an included angle between the upper bottom surface and the side surface of the base island is an obtuse angle, the greater the thickness of the frame 100 is, the greater the area difference between a lower bottom surface and the upper bottom surface of the base island is, and the more obvious the heat dissipation effect of the corresponding trapezoidal base island is.

The frame 100 includes a plurality of component areas A. The component areas A are used for manufacturing single package bodies.

In the embodiment, the frame 100 includes a first surface 103 and a second surface 104 facing away from the first surface 103. A first surface 103 of the component area A includes a first region I and a second region II located around the first region I. The first region I is used for subsequently forming the base island, and the second region II is used for subsequently forming the lead.

As an example, the first region I is located in the center of the component area A. In other embodiments, the first region I or may be located on one side of the component area A in an offset manner according to different technological layouts.

With reference to FIG. 2, the frame 100 is obliquely segmented to form a plurality of spaced base islands 101 and a plurality of spaced electrically-conductive structures 102, so as to enable sections of the base islands 101 to be trapezoidal and sections of the electrically-conductive structures 102 to be inverted-trapezoidal.

First, it should be noted that a trapezoid is a quadrangle, and opposite parallel sides are referred to as bases of the trapezoid. A longer base is referred to as a lower base, and a shorter base is referred to as an upper base.

In the package method according to the embodiments of the present disclosure, the frame 100 is obliquely segmented to form the plurality of spaced base islands 101 and the plurality of spaced electrically-conductive structures 102, so as to enable the sections of the base islands 101 to be trapezoidal. Moreover, in the subsequent package process, dies are formed on the upper bottom surfaces of the trapezoidal base islands 101. In other words, in the package structure, the dies are in contact with smaller-sized surfaces of the base islands 101. Larger-sized lower bottom surfaces of the base islands 101 are used for dissipating heat. Thus, the heat generated by the dies is rapidly dissipated to cool the dies, the dies operate normally, and a heat dissipation effect of the package structure is improved.

In the package method according to the embodiments of the present disclosure, after the frame 100 is obliquely segmented, the sections of the electrically-conductive structures 102 are inverted-trapezoidal, and the sections of the base islands 101 are trapezoidal. Thus, lower bottom surfaces of the electrically-conductive structures 102 and the upper bottom surfaces of the base islands 101 are located at a same horizontal position, and upper bottom surfaces of the electrically-conductive structures 102 and lower bottom surfaces of the base islands 101 are located at a same horizontal position. An area of the lower bottom surfaces of the electrically-conductive structures 102 is greater than that of the upper bottom surfaces of the electrically-conductive structures. Subsequently, after the dies are subsequently arranged on the upper bottom surfaces of the trapezoidal base islands 101, one ends of the lower bottom surfaces of the electrically-conductive structures 102 are closer to the dies, and the electrically-conductive structures 102 are connected to the dies through wires. Then, the electrically-conductive structures 102 between adjacent dies are segmented to form spaced leads.

It should be further noted that compared with a case where electrically-conductive structures and base islands employ step structures, the sections of the electrically-conductive structures 102 are inverted-trapezoidal, and the sections of the base islands 101 are trapezoidal, so that the electrically-conductive structures 102 and the base islands 101 are structurally stabler, and a stable wire bonding platform can be provided for a subsequent wire bonding technology.

In the embodiment, with a direction perpendicular to the upper bottom surface of the trapezoidal base island 101 as a first direction, in the step that the frame 100 is obliquely segmented, overlapping regions are provided between the base islands 101 and the electrically-conductive structures 102 in the first direction. Thus, the lower bottom surfaces of the base islands 101 are as large as possible, a heat dissipation capability of the base islands 101 is improved, and a degree of integration of the package structure finally formed is increased.

Specifically, when the overlapping regions are provided between the base islands 101 and the electrically-conductive structures 102 in the first direction, partial lower bottom surfaces of the base islands 101 are located below the lower bottom surfaces of the electrically-conductive structures 102. In addition, an included angle β1 (as shown in FIG. 2) between side surfaces and the lower bottom surfaces of the base islands 101 overlap an included angles β2 (as shown in FIG. 2) between side surfaces and the lower bottom surfaces of the electrically-conductive structure 102. Also, partial side surfaces 101a of the base islands 101 are located below the side surfaces 102a of the electrically-conductive structures 102.

In the embodiment, in the step that the frame 100 is obliquely segmented, the side surfaces 101a of the trapezoidal base islands 101 are parallel to the side surfaces 102a of the inverted-trapezoidal electrically-conductive structures 102. Specifically, the side surfaces 101a of the base islands 101 are parallel to the side surfaces 102a of the electrically-conductive structures 102, so that distances between the base islands 101 and the electrically-conductive structures 102 are uniform. Accordingly, no short circuit is likely to occur between the base islands 101 and the electrically-conductive structures 102, and the base islands 101 and the electrically-conductive structures 102 can also be more structurally compact.

It should be further noted that the side surfaces 101a of the base islands 101 are parallel to the side surfaces 102a of the electrically-conductive structures 102, so that an included angle α1 (as shown in FIG. 2) between the side surfaces of the base islands 101 and the upper bottom surfaces of the base islands 101 is equal to an included angle α2 (as shown in FIG. 2) between the side surfaces of the electrically-conductive structures 102 and the lower bottom surfaces of the electrically-conductive structures 102.

In the embodiment, with a direction parallel to the surfaces of the base islands 101 and perpendicular to junctions between the first regions I and the second regions II as a width direction, a width size of the lower bottom surfaces of the base islands 101 is adjusted along with changes in die size. As an example, a width of the base islands 101 ranges from 6 mm to 20 mm.

In the embodiment, in the step that the frame 100 is obliquely segmented, the included angle α1 between the upper bottom surfaces and the side surfaces of the trapezoidal base islands 101 is greater than or equal to 135° and less than or equal to 150°. If the included angle α1 between the upper bottom surfaces and the side surfaces of the base islands 101 is too large, and a size of the upper bottom surfaces of the corresponding electrically-conductive structures 102 is too small, a size of upper bottom surfaces of the leads formed is too small after the electrically-conductive structures 102 are segmented subsequently. When the upper bottom surfaces of the leads are mounted to a substrate subsequently, bonding strength between the leads and the substrate is affected. In addition, if the included angle α1 between the upper bottom surfaces and the side surfaces of the base islands 101 is too large, difficulties in obliquely segmenting the frame 100 are increased, which is not conducive to improvement of a yield of the package structure finally formed. If the included angle α1 between the upper bottom surfaces and the side surfaces of the base islands 101 is too small, a width size of the lower bottom surfaces of the base islands 101 is small, and a corresponding area is small. Thus, a heat dissipation capability of the base islands 101 is reduced. Consequently, energy of the dies fails to be emitted out in time, and performance of the package structure is reduced.

It should be noted that the larger the included angle α1 between the upper bottom surfaces and the side surfaces of the base islands 101 is, the larger the width of the lower bottom surfaces of the base islands 101 is, the larger the corresponding area of the lower bottom surfaces of the base islands 101 is, and the more obvious the heat dissipation effect of the dies is. For example, when the included angle between the upper bottom surfaces and the side surfaces of the base islands 101 is 140°, a maximum temperature of the dies is 101.2° C. When the included angle between the upper bottom surfaces and the side surfaces of the base islands 101 is 145°, a maximum temperature of the dies is 97° C. When the included angle between the upper bottom surfaces and the side surfaces of the base islands 101 is 150°, a maximum temperature of the dies is 95.7° C.

In the embodiment, in the step that the frame 100 is obliquely segmented, spacing gaps formed between the base islands 101 and the electrically-conductive structures 102 are oblique downwards from the first surface 103 to the second surface 104. The spacing gaps are oblique downwards. In a subsequent step that a plastic package layer is formed, a plastic package material fills the spacing gaps under the effect of gravity. Thus, efficiency of filling the spacing spaces is improved, and a formation quality of the plastic package layer is enhanced.

In the embodiment, the step that the frame 100 is obliquely segmented includes: the frame 100 is etched through a plasma etching technology. Specifically, the frame 100 is etched through a plasma dry etching technology. The dry etching technology features anisotropic etching and has good etching profile controllability. Thus, the side surfaces 101a of the base islands 101 are parallel to the side surfaces 102a of the electrically-conductive structures 102. In other embodiments, the frame 100 or may be segmented through a laser cutting technology.

In the embodiment, the step that the frame 100 is obliquely segmented includes: oblique segmentation is performed on the first surface 103 to the second surface 104 along the junction between the first region I and the second region II in an oblique direction facing away from the first region I, so as to form the trapezoidal base islands 101 and the inverted-trapezoidal electrically-conductive structures 102. In an oblique segmentation process, the oblique direction faces away from the first region I, so that the base islands 101 are of a trapezoidal structure, and the electrically-conductive structures 102 are of an inverted-trapezoidal structure.

It should be noted that the electrically-conductive structures 102 span boundaries between adjacent component areas A. It can be seen from FIG. 2 that one conductive structure 102 is located in second regions II of two component areas A. In the subsequent package process, after segmentation along the boundaries between the adjacent component areas A is performed, spaced leads are formed, and different leads are located in different component areas A.

It should be further noted that only parts of the electrically-conductive structures 102 on two side edges in FIG. 2 are illustratively shown. With reference to FIG. 3, dies 105 are arranged on the upper bottom surfaces of the trapezoidal base islands 101.

The dies 105 are arranged on the base islands 101. During operation of the package structure formed subsequently, the base islands 101 absorb heat from the dies 105 through smaller-sized upper bottom surfaces and dissipate the heat through larger-sized lower bottom surfaces. Thus, the heat of the dies 105 can be rapidly dissipated to cool the dies 105, and a heat dissipation effect of the package structure can be improved.

In the embodiment, the dies 105 are mounted to the upper bottom surfaces of the base islands 101 through adhesive films 106. The adhesive film 106 includes a die attach film (DAF). The die attach film has good adhesion performance, and thus a package technology can be simplified, and manufacturing efficiency can be improved. In other embodiments, the dies or may be formed on the upper bottom surfaces of the base islands through a surface mount technology (SMT).

It should be noted that to facilitate mounting of the dies 105, a width of the upper bottom surfaces of the base islands 101 is greater than a width of the dies 105, and the width of the upper bottom surfaces of the base islands 101 is at least 1.5 times the width of the dies 105.

In the embodiment, electrical connection ends of the dies 105 are located on tops of the dies 105. In other embodiments, electrical connection ends of the dies or may be located on side walls of the dies.

With reference to FIG. 4, end portions of the lower bottom surfaces of the electrically-conductive structures 102 are connected to the dies 105 through wires 107.

The wires 107 are used for electrically connecting the dies 105 to the electrically-conductive structures 102.

In the embodiment, the electrically-conductive structures 102 are electrically connected to the dies 105 through a wire bonding technology.

In the embodiment, the wires 107 are electrically-conductive wires, and a material of the wires 107 includes gold, copper, or aluminum. Correspondingly, the wires 107 may be gold wires, copper wires, or aluminum wires.

In a subsequent package technology, the electrically-conductive structures 102 need to be segmented along central positions of the electrically-conductive structures 102. Thus, the end portions of the lower bottom surfaces of the electrically-conductive structures 102 are connected to the wires 107, so that damage to the wires 107 in a subsequent process of segmenting the electrically-conductive structures 102 can be avoided.

The electrical connection ends of the dies 105 are located on the tops of the dies 105. Correspondingly, the wires 107 electrically connect the lower bottom surfaces of the electrically-conductive structures 102 to the electrical connection ends on the tops of the dies 105. In other embodiments, since electrical connection ends of the dies are located on side walls of the dies, the wires electrically connect the electrically-conductive structures to the electrical connection ends on the side walls of the dies.

In the embodiment, since the area of the lower bottom surfaces of the electrically-conductive structures 102 is greater than that of the upper bottom surfaces, the lower bottom surfaces of the electrically-conductive structures 102 are closer to the dies 105, and the wires 107 are short. After the electrically-conductive structures 102 between the adjacent dies 105 are segmented into spaced leads subsequently, parasitic resistance between the leads and the dies 105 can be reduced, and package costs can be decreased.

With reference to FIG. 5, the package method further includes: a plastic package layer 108 covering the dies 105, the base islands 101, and the electrically-conductive structures 102 is formed before the electrically-conductive structures 102 between the adjacent dies 105 are segmented.

The plastic package layer 108 is used for packaging the dies 105, the base islands 101, and the electrically-conductive structures 102 together, so as to well protect the dies 105, the base islands 101, and the electrically-conductive structures 102.

In the embodiment, a material of the plastic package layer 108 may be epoxy resin, polyimide resin, benzocyclobutene resin, or polybenzoxazole resin that contains filler. The material or may be polybutylene terephthalate, polycarbonate, polyethylene terephthalate, polyethylene, polypropylene, polyolefin, polyurethane, polyolefin, polyethersulfone, polyamide, polyurethane, an ethylene-vinyl acetate copolymer, or polyvinyl alcohol that contains filler. In an embodiment, the filler may be inorganic filler or organic filler.

It should be noted that in a process of forming the plastic package layer 108, the plastic package layer 108 covers the wires 107. Thus, the wires 107 are not exposed outside the plastic package layer 108, and bridging or short circuit between plastic package bodies formed subsequently and other circuit elements due to the exposed wires 107 is avoided.

In the embodiment, the plastic package layer is formed through a transfer molding technology. Through the transfer molding technology, a use amount of the plastic package material can be precisely controlled, material waste can be reduced, the material can be uniformly distributed, no defect such as bubbles can be generated in the plastic package layer, and reliability of the package structure can be improved.

It should be noted that the spacing gaps formed between the base islands 101 and the electrically-conductive structures 102 are oblique downwards from the first surface 103 to the second surface 104. Since the spacing gaps are oblique downwards, in a step that the plastic package layer is formed through the transfer molding technology, the plastic package layer fills the spacing gaps under the effect of gravity. Thus, filling efficiency of the plastic package layer is improved.

With reference to FIG. 6, the electrically-conductive structures 102 between the adjacent dies 105 are segmented to form spaced leads 109.

The electrically-conductive structures 102 between the adjacent dies 105 are segmented, so that a package body in each component area A is separated from one another, and the package body is mounted to the substrate subsequently.

In the embodiment, the electrically-conductive structures 102 between the adjacent dies 105 are segmented through the laser cutting technology. In other embodiments, the electrically-conductive structures between the adjacent dies or may be segmented through the dry etching technology. In some other embodiments, the electrically-conductive structures between the adjacent dies 105 or may be segmented though a cutter.

It should be noted that in a process of segmenting the electrically-conductive structures 102 between the adjacent dies 105, segmentation is performed along the centers of the electrically-conductive structures 102, so that widths of the leads 109 formed in the two component areas A are equal to each other. From another perspective, the centers of the electrically-conductive structures 102 correspond to boundaries between adjacent component areas.

It should be noted that in the step of the electrically-conductive structures 102 are segmented, the plastic package layer 108 is further segmented.

In the embodiment, the lower bottom surfaces of the base islands 101 are exposed outside the plastic package layer 108, and the leads 109 surround the base islands 101 for electrical connection. Thus, the package bodies employ a quad flat no-lead package (QFN). The plastic package layer 108 exposes the lower bottom surfaces of the base islands 101. Since the area of the lower bottom surfaces of the base islands 101 is large, a heat dissipation effect of the package structure is optimized.

A formation method for the package structure further includes: a substrate (not shown in the figure) is provided; and a package body is mounted to the substrate.

In the embodiment, the substrate is internally provided with a circuit. Specifically, the substrate is a printed circuit board (PCB). In other embodiments, the substrate or may be a package substrate.

In the embodiment, the substrate is provided with exposed connection terminals, so as to be electrically connected to the leads 109 of the package bodies and used for supplying power to the package bodies or transmitting an electrical signal. As an example, the connection terminals may be soldering pads of the substrate. The substrate is further provided with a thermal channel. The thermal channel is electrically connected to the base islands 101 of the package bodies and used for transferring heat from the base islands 101 to the other side of the substrate for heat dissipation.

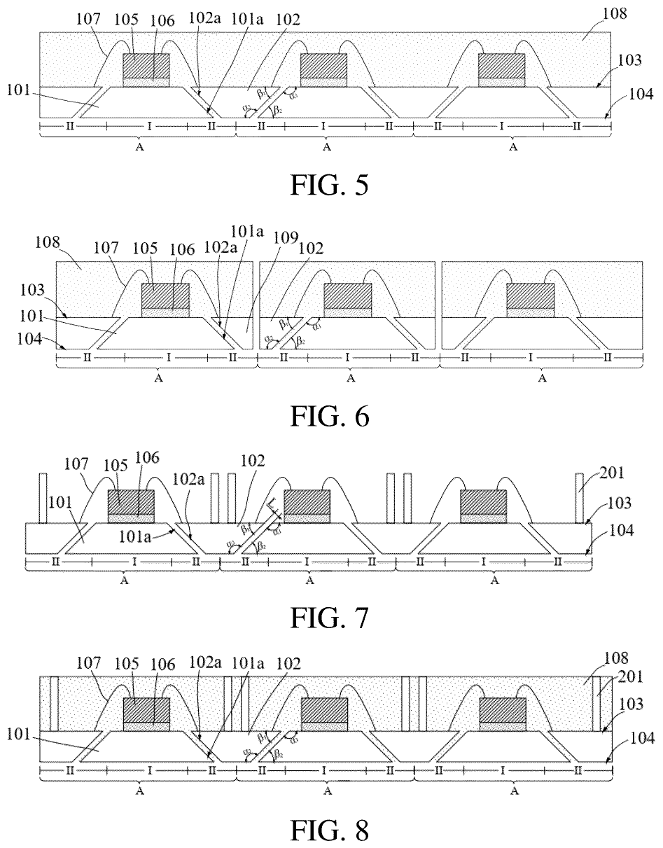

With reference to FIG. 7 to FIG. 9, schematic structural diagrams corresponding to all steps in a second embodiment of a package method according to the present disclosure are shown.

The similarities between the embodiment of the present disclosure and the first embodiment will not be repeated herein. The differences lie in that

with reference to FIG. 7, after dies 105 are formed on base islands 101 and before electrically-conductive structures 102 between adjacent dies 105 are segmented, a plurality of spaced cylindrical connection pillars 201 are formed on the electrically-conductive structures 102, where the cylindrical connection pillars 201 are located in different component areas A.

In the embodiment, two cylindrical connection pillars 201 are arranged on one electrically-conductive structure 102.

In the embodiment, the cylindrical connection pillars 201 are formed on the electrically-conductive structure 102 through the surface mount technology.

With reference to FIG. 8, in a step that a plastic package layer 108 is formed, the plastic package layer 108 covers side walls of the cylindrical connection pillars 201 and exposes tops of the cylindrical connection pillars 201. The plastic package layer 108 is exposed at the tops of the cylindrical connection pillars 201. Thus, after formed subsequently, package bodies are electrically connected to other circuit elements through the cylindrical connection pillars 201. Also, the tops of the cylindrical connection pillars 201 and the base islands 101 are exposed from two opposite surfaces of the plastic package layer 108 respectively. Subsequently, the base islands 101 may be installed to the PCB through the tops of the cylindrical connection pillars 201, so as to dissipate heat upwards. Furthermore, heat dissipators may be arranged on the base islands 101.

The base islands 101 having the lower bottom surfaces large in area cooperate with the large-sized heat dissipators, so that a heat dissipation capability of the package structure of the present disclosure can be further improved.

It should be noted that the step that a plastic package layer 108 is formed includes: planarization operation is performed with the tops of the cylindrical connection pillars 201 as planarization positions after a plastic package layer is formed.

With reference to FIG. 9, in the step that electrically-conductive structures 102 between adjacent dies 105 are segmented, segmentation is performed along boundaries between adjacent component areas A, so that different cylindrical connection pillars 201 are located on different leads 109 respectively.

In the embodiment of the present disclosure, each segmented package body is provided with the cylindrical connection pillar. Thus, the package bodies are electrically connected to other circuit elements through the cylindrical connection pillars in the subsequent package technology.

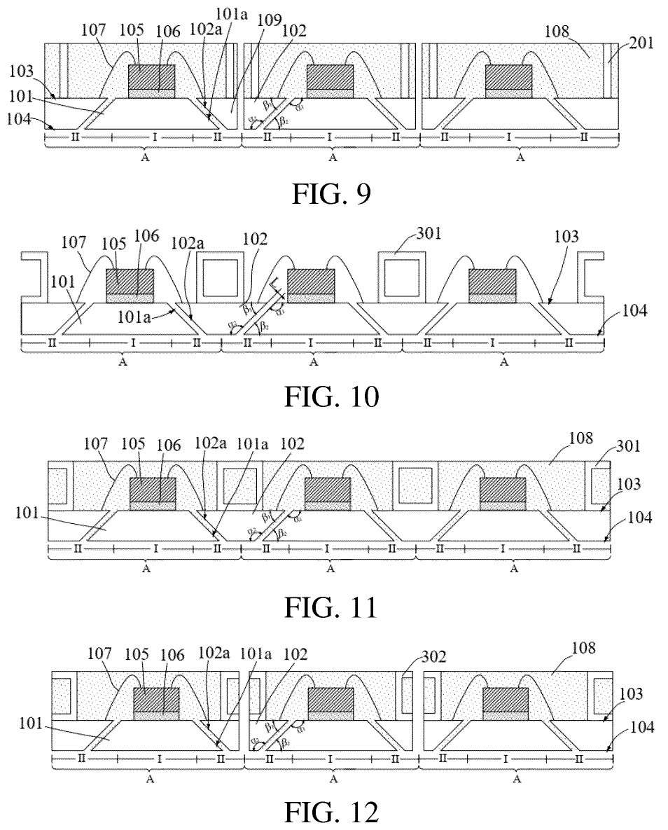

With reference to FIG. 10 to FIG. 12, schematic structural diagrams corresponding to all steps in a third embodiment of a package method according to the present disclosure are shown.

The similarities between the embodiment of the present disclosure and the first embodiment will not be repeated herein. The differences lie in that

with reference to FIG. 10, after dies 105 are formed on base islands 101 and before electrically-conductive structures 102 between adjacent dies 105 are segmented, hollow rectangular structures 301 are formed on the electrically-conductive structures 102.

In the embodiment, the hollow rectangular structures 301 span different component areas A. Thus, connection pillars are formed in different component areas A after the hollow rectangular structures 301 are segmented subsequently.

In the embodiment, the hollow rectangular structures 301 are formed on the electrically-conductive structures 102 through the surface mount technology.

With reference to FIG. 11, in a step that a plastic package layer 108 is formed, the plastic package layer 108 further covers side walls of the hollow rectangular structures 301 and exposes tops of the hollow rectangular structures 301. The plastic package layer 108 is exposed at the tops of the hollow rectangular structures 301. Subsequently, after the hollow rectangular structures 301 are segmented, the connection pillars are formed, and the plastic package layer 108 is exposed at tops of the corresponding connection pillars. Thus, package bodies are electrically connected to other circuit elements through the connection pillars.

It should be noted that in the step that a plastic package layer 108 is formed, planarization operation is performed with the tops of the hollow rectangular structures 301 as planarization positions after a plastic package layer is formed.

With reference to FIG. 12, in the step that electrically-conductive structures 102 between adjacent dies 105 are segmented, the hollow rectangular structures 301 are segmented along boundaries between adjacent component areas A. Thus, C-shaped connection pillars 302 having openings facing away from the dies 105 are formed on different leads 109.

In the embodiment, the openings of the C-shaped connection pillars in the package bodies face away from the dies 105.

In the embodiment of the present disclosure, each segmented package body is provided with the C-shaped connection pillar, so that the package bodies are electrically connected to other circuit elements through the C-shaped connection pillars in a subsequent package technology.

A package structure is further provided in the embodiments of the present disclosure. With reference to FIG. 6, the first embodiment for implementing the package structure of the present disclosure is illustratively shown.

The package structure includes: a base island 101, where a section of the base island 101 is trapezoidal; a die 105, where the die is located on an upper bottom surface of the trapezoidal base island 101; a lead 109, where the lead is spaced from the base island 101, and a section of the lead 109 is inverted-trapezoidal; and a wire 107, where the wire electrically connects the lead 109 to the die 105.

First, it should be noted that a trapezoid is a quadrangle, and opposite parallel sides are referred to as bases of the trapezoid. A longer base is referred to as a lower base, and a shorter base is referred to as an upper base.

In the package structure according to the embodiments of the present disclosure, the die 105 is in contact with a smaller-sized upper bottom surface of the base island 101. The smaller-sized upper bottom surface receives heat generated by the die 105, and a larger-sized lower bottom surface of the base island 101 is used for dissipating the heat. Thus, the heat generated by the die 105 is rapidly dissipated to cool the die 105, the die 105 operates normally, and a heat dissipation effect of the package structure is improved. In addition, the inverted-trapezoidal lead 109 has a larger-sized lower bottom surface to facilitate formation of the wire between the lead 109 and the die 105, so that technology reliability is improved.

In addition, since the area of the lower bottom surface of the lead 109 is greater than that of the upper bottom surface, the lower bottom surface of the lead 109 is closer to the die 105, and the lead 109 is connected to the die 105 through the wire 107. Owing to the short wire 107, parasitic resistance between the lead and the die 105 can be reduced.

It should be further noted that compared with a case where a lead and a base island employ step structures, the section of the lead 109 is inverted-trapezoidal, and the section of the base island 101 is trapezoidal, so that a stable wire bonding platform can be provided for a subsequent wire bonding technology.

In the embodiment, the leads 109 are located around the base islands 101.

In the embodiment, materials of the base islands 101 and the leads 109 are identical. The material includes, but is not limited to, one or more of gold, copper, nickel, and tin.

In the embodiment, the base islands 101 and the leads 109 are formed by obliquely segmenting a same frame, so that the base islands 101 and the leads 109 have an identical thickness.

In the embodiment, a thickness of the base islands 101 is 0.3 mm to 0.7 mm. If the thickness of the base islands 101 is greater, time for obliquely segmenting the frame 100 will be long, which is not conducive to reduction in a period of the package method. In addition, unnecessary material waste will be caused. If the thickness of the base islands 101 is smaller, side surfaces (i.e. side surfaces 101a and side surfaces 102a), closest to each other, of the base islands 101 and the leads 109 are non-flat, and thus difficulties in machining the base islands 101 and the leads 109 are increased. In addition, since the base islands 101 formed subsequently are trapezoidal, and an included angle between the upper bottom surfaces and the side surfaces of the base islands 101 is an obtuse angle, the greater the thickness of the frame 100 is, the greater the area difference between lower bottom surfaces and the upper bottom surfaces of the base islands 101 is, and the more obvious the heat dissipation effect of the corresponding trapezoidal base islands 101 is.

In the embodiment, with a direction perpendicular to the upper bottom surfaces of the trapezoidal base islands 101 as a first direction, overlapping regions are provided between the base islands 101 and the leads 109 in the first direction. Thus, the lower bottom surfaces of the base islands 101 are as large as possible, a heat dissipation capability of the base islands 101 is improved, and a degree of integration of the package structure finally formed is increased.

Specifically, when the overlapping regions are provided between the base islands 101 and the leads 109 in the first direction, partial lower bottom surfaces of the base islands 101 are located below the lower bottom surfaces of the leads 109. In addition, an included angle β1 (as shown in FIG. 2) between the side surfaces and the lower bottom surfaces of the base islands 101 overlap an included angles β2 (as shown in FIG. 2) between the side surfaces and the lower bottom surfaces of the leads 109. Also, partial side surfaces 101a of the base islands 101 are located below the side surfaces 102a of the leads 109.

In the embodiment, the side surfaces 101a of the trapezoidal base islands 101 are parallel to the side surfaces 102a of the inverted-trapezoidal leads 109. Specifically, two side surfaces, closest to each other, of the base islands 101 and the leads 109 are parallel to each other, so that distances between the base islands 101 and the leads 109 are uniform. Accordingly, no short circuit is likely to occur between the base islands 101 and the leads 109, and the base islands 101 and the leads 109 can also be more structurally compact.

It should be further noted that the side surfaces 101a of the base islands 101 are parallel to the side surfaces 102a of the leads 109, so that an included angle α1 (as shown in FIG. 6) between the side surfaces of the base islands 101 and the upper bottom surfaces of the base islands 101 is equal to an included angle α2 (as shown in FIG. 6) between the side surfaces of the leads 109 and the lower bottom surfaces of the leads 109.

In the embodiment, with a direction parallel to the surfaces of the base islands 101 and perpendicular to junctions between first regions I and second regions II as a width direction, a width size of the lower bottom surfaces of the base islands 101 is adjusted along with changes in die size. As an example, a width of the base islands 101 ranges from 6 mm to 20 mm.

In the embodiment, the included angle between the upper bottom surfaces and the side surfaces of the trapezoidal base islands 101 is greater than or equal to 135° and less than or equal to 150°. If the included angle α1 between the upper bottom surfaces and the side surfaces of the base islands 101 is too large, and a size of the upper bottom surfaces of the corresponding leads 109 is too small, when the upper bottom surfaces of the leads are mounted to a substrate, bonding strength between the leads and the substrate is affected. If the included angle α1 between the upper bottom surfaces and the side surfaces of the base islands 101 is too small, a width size of the lower bottom surfaces of the base islands 101 is small, and a corresponding area is small. Thus, a heat dissipation capability of the base islands 101 is reduced. Consequently, energy of the dies 105 fails to be emitted out in time, and performance of the package structure is reduced.

It should be noted that the larger the included angle α1 between the upper bottom surfaces and the side surfaces of the base islands 101 is, the larger the width of the lower bottom surfaces of the base islands 101 is, the larger the corresponding area of the lower bottom surfaces of the base islands 101 is, and the more obvious the heat dissipation effect of the dies is. For example, when the included angle between the upper bottom surfaces and the side surfaces of the base islands 101 is 140°, a maximum temperature of the dies is 101.2° C. When the included angle between the upper bottom surfaces and the side surfaces of the base islands 101 is 145°, a maximum temperature of the dies is 97° C. When the included angle between the upper bottom surfaces and the side surfaces of the base islands 101 is 150°, a maximum temperature of the dies is 95.7° C.

The package structure further includes: a plastic package layer 108, where the plastic package layer covers the dies 105 and the wires 107 and fills portions between the leads 109 and the base islands 101.

In the embodiment, a material of the plastic package layer 108 may be epoxy resin, polyimide resin, benzocyclobutene resin, or polybenzoxazole resin that contains filler. The material or may be polybutylene terephthalate, polycarbonate, polyethylene terephthalate, polyethylene, polypropylene, polyolefin, polyurethane, polyolefin, polyethersulfone, polyamide, polyurethane, an ethylene-vinyl acetate copolymer, or polyvinyl alcohol that contains filler. In an embodiment, the filler may be inorganic filler or organic filler.

It should be noted that the plastic package layer 108 covers the wires 107. Thus, the wires 107 are not exposed outside the plastic package layer 108, and bridging or short circuit between plastic package bodies formed subsequently and other circuit elements due to the exposed wires 107 is avoided.

It should be noted that spacing gaps formed between the base islands 101 and the leads 109 are oblique downwards from a first surface 103 to a second surface 104. Since the spacing gaps are oblique downwards, in a step where the transfer molding technology is employed, the plastic package material fills the spacing gaps under the effect of gravity. Thus, filling efficiency of the plastic package layer 108 is improved.

In the embodiment, the spacing gaps formed between the base islands 101 and the leads 109 are oblique downwards from the first surface 103 to the second surface 104. The spacing gaps are oblique downwards to facilitate filling by the plastic package layer.

In the embodiment, the dies 105 are mounted to the upper bottom surfaces of the base islands 101 through adhesive films 106. The adhesive film 106 includes a die attach film (DAF). The die attach film has good adhesion performance, and thus a package technology can be simplified, and manufacturing efficiency can be improved. In other embodiments, the dies or may be formed on the upper bottom surfaces of the base islands through a surface mount technology (SMT).

It should be noted that to facilitate mounting of the dies 105, a width of the upper bottom surfaces of the base islands 101 is greater than a width of the dies 105, and the width of the upper bottom surfaces of the base islands 101 is at least 1.5 times the width of the dies 105.

In the embodiment, electrical connection ends of the dies 105 are located on tops of the dies 105. In other embodiments, electrical connection ends of the dies 105 or may be located on side walls of the dies 105.

The wires 107 are used for electrically connecting the dies 105 to the leads 109.

In the embodiment, the wires 107 are electrically-conductive wires, and a material of the wires 107 includes gold, copper, or aluminum. Correspondingly, the wires 107 may be gold wires, copper wires, or aluminum wires.

The electrical connection ends of the dies 105 are located on the tops of the dies 105. Correspondingly, the wires 107 electrically connect the lower bottom surfaces of the leads 109 to the electrical connection ends on the tops of the dies 105. In other embodiments, since electrical connection ends of the dies are located on side walls of the dies, the wires electrically connect the leads 109 to the electrical connection ends on the side walls of the dies 105.

In the embodiment, since the area of the lower bottom surfaces of the leads 109 is greater than that of the upper bottom surfaces, the lower bottom surfaces of the leads 109 are closer to the dies 105, and the wires 107 are short. Thus, parasitic resistance between the leads 109 and the dies 105 can be reduced, and package costs can be decreased.

It should be further noted that in the package structure, the lower bottom surfaces of the base islands 101 are exposed outside the plastic package layer, and the leads 109 surround the base islands 101 for electrical connection. Thus, the package bodies employ a quad flat no-lead package (QFN). The plastic package layer 108 exposes the lower bottom surfaces of the base islands 101. Since the area of the lower bottom surfaces of the base islands 101 is large, a heat dissipation effect of the package structure is optimized.

The package structure further includes: a substrate (not shown in the figure), where the package bodies are located on the substrate, and the package body includes the base island 101, the lead 109, the die 105, the wire 107, and the plastic package layer 108.

In the embodiment, the substrate is internally provided with a circuit. Specifically, the substrate is a printed circuit board (PCB). In other embodiments, the substrate or may be a package substrate.

In the embodiment, the substrate is provided with exposed connection terminals, so as to be electrically connected to the leads 109 of the package bodies and used for supplying power to the package bodies or transmitting an electrical signal. As an example, the connection terminals may be soldering pads of the substrate. The substrate is further provided with a thermal channel. The thermal channel is electrically connected to the base islands 101 of the package bodies and used for transferring heat from the base islands 101 to the other side of the substrate for heat dissipation.

With reference to FIG. 9, the second embodiment for implementing the package structure according to the present disclosure is illustratively shown.

The similarities between the embodiment of the present disclosure and the first embodiment will not be repeated herein. The differences lie in that the package structure further includes: connection pillars 201, where the connection pillars are located on the lower bottom surfaces of the inverted-trapezoidal leads 109.

In the embodiment, the connection pillars are cylindrical connection pillars.

The plastic package layer 108 covers side walls of the cylindrical connection pillars 201 and exposes tops of the cylindrical connection pillars 201. The plastic package layer 108 is exposed at the tops of the cylindrical connection pillars 201. Thus, after formed subsequently, the package bodies are electrically connected to other circuit elements through the cylindrical connection pillars 201. Also, the tops of the cylindrical connection pillars 201 and the base islands 101 are exposed from two opposite surfaces of the plastic package layer 108 respectively. Subsequently, the base islands 101 may be installed to a PCB through the tops of the cylindrical connection pillars 201, so as to dissipate heat upwards. Furthermore, heat dissipators may be arranged on the base islands 101. The base islands 101 having the lower bottom surfaces large in area cooperate with the large-sized heat dissipators, so that a heat dissipation capability of the package structure of the present disclosure can be further improved.

With reference to FIG. 12, the third embodiment for implementing the package structure according to the present disclosure is illustratively shown.

The similarities between the embodiment of the present disclosure and the first embodiment will not be repeated herein. The differences lie in that the package structure further includes: connection pillars 302, where the connection pillars are located on the lower bottom surfaces of the inverted-trapezoidal leads 109.

In the embodiment, the connection pillars are C-shaped connection pillars 302 having openings facing away from the dies.

The plastic package layer 108 further covers side walls of the C-shaped connection pillars 302 and exposes tops of the C-shaped connection pillars 302. Thus, the package bodies are electrically connected to other circuit elements through the connection pillars.

The package structure may be formed through the formation method in the foregoing embodiment or other formation methods. Reference can be made to the corresponding description in the foregoing embodiment for the specific description of the package structure in the embodiment, which will not be repeated in the embodiment.

Although disclosed as above, the present disclosure is not limited to the foregoing description. A person skilled in the art can make various changes and modifications without departing from the spirit and the scope of the present disclosure. Thus, the scope of protection of the present disclosure should be subject to the scope defined by the claims.

What is claimed is:

1. A package structure, comprising:
a base island, wherein a section of the base island is trapezoidal;
a die, wherein the die is located on an upper bottom surface of the trapezoidal base island;
a lead, wherein the lead is spaced from the base island, and a section of the lead is inverted-trapezoidal; and
a wire, wherein the wire electrically connects the lead to the die.

2. The package structure according to claim 1, wherein a side surface of the trapezoidal base island is parallel to a side surface of the inverted-trapezoidal lead.

3. The package structure according to claim 1, wherein with a direction perpendicular to the upper bottom surface of the trapezoidal base island as a first direction, an overlapping region is provided between the base island and the lead in the first direction.

4. The package structure according to claim 1, wherein an included angle between the upper bottom surface and a side surface of the trapezoidal base island is greater than or equal to 135° and less than or equal to 150°.

5. The package structure according to claim 1, further comprising:
a connection pillar, wherein the connection pillar is located on a lower bottom surface of the inverted-trapezoidal lead.

6. The package structure according to claim 5, wherein the connection pillar is a cylindrical connection pillar or a C-shaped connection pillar having an opening facing away from the die.

7. The package structure according to claim 1, further comprising:
a plastic package layer, wherein the plastic package layer covers the die and the wire and fills a portion between the lead and the base island.

8. A package method, comprising:
providing a frame;
obliquely segmenting the frame to form a plurality of spaced base islands and a plurality of spaced electrically-conductive structures, so as to enable sections of the base islands to be trapezoidal and sections of the electrically-conductive structures to be inverted-trapezoidal;
arranging dies on upper bottom surfaces of the trapezoidal base islands;
connecting end portions of lower bottom surfaces of the electrically-conductive structures to the dies through wires; and
segmenting electrically-conductive structures between adjacent dies, so as to form spaced leads.

9. The package method according to claim 8, wherein in the obliquely segmenting the frame, side surfaces of the trapezoidal base islands are parallel to side surfaces of the inverted-trapezoidal electrically-conductive structures.

10. The package method according to claim 8, wherein in the obliquely segmenting the frame, with a direction perpendicular to the upper bottom surface of the trapezoidal base island as a first direction, an overlapping region is provided between the base island and the electrically-conductive structure in the first direction.

11. The package method according to claim 8, wherein the obliquely segmenting the frame comprises: etching the frame through a plasma etching technology or cutting the frame through a laser cutting technology.

12. The package method according to claim 8, wherein in the obliquely segmenting the frame, an included angle between the upper bottom surface and a side surface of the trapezoidal base island is greater than or equal to 135° and less than or equal to 150°.

13. The package method according to claim 8, wherein in the providing a frame, the frame comprises a first surface and a second surface facing away from the first surface, the frame comprises a plurality of component areas, and first surfaces of the component areas comprise first regions and second regions located around the first regions; and
the obliquely segmenting the frame comprises: performing oblique segmentation on the first surface to the second surface along a junction between the first region and the second region in an oblique direction facing away from the first region, so as to form the trapezoidal base island and the inverted-trapezoidal electrically-conductive structure, and the electrically-conductive structure spans a boundary between adjacent component areas.

14. The package method according to claim 8, further comprising: forming a plastic package layer covering the dies, the base islands, and the electrically-conductive structures before the electrically-conductive structures between the adjacent dies are segmented; and
in the segmenting electrically-conductive structures, the plastic package layer is further segmented.

15. The package method according to claim 8, in the providing a frame, the frame comprises a plurality of component areas, and the component areas comprise first regions and second regions located around the first regions;
in the obliquely segmenting the frame, the electrically-conductive structures span boundaries between adjacent component areas;
the package method further comprises: forming a plurality of spaced cylindrical connection pillars on the electrically-conductive structures after the dies are formed on the base islands and before the electrically-conductive structures between the adjacent dies are segmented, wherein the cylindrical connection pillars are located in different component areas; and
in the segmenting electrically-conductive structures between adjacent dies, segmentation is performed along the boundaries between the adjacent component areas, so as to enable different cylindrical connection pillars to be located on different leads respectively.

16. The package method according to claim 8, wherein in the providing a frame, the frame comprises a plurality of component areas, and the component areas comprise first regions and second regions located around the first regions;
in the obliquely segmenting the frame, the electrically-conductive structures span boundaries between adjacent component areas;
the package method further comprises: forming hollow rectangular structures on the electrically-conductive structures after the dies are formed on the base islands and before the electrically-conductive structures between the adjacent dies are segmented, wherein the electrically-conductive structures span the boundaries between the adjacent component areas; and
in the segmenting electrically-conductive structures between adjacent dies, the hollow rectangular structures are segmented along the boundaries between the adjacent component areas, so as to form C-shaped connection pillars having openings facing away from the dies on different leads.
